(19) United States
(12) Patent Application Publication
(10) Pub. No.: US 2025/0194090 A1
(43) Pub. Date: Jun. 12, 2025

(54) Integrated Circuitry, Memory Circuitry, And Method Of Forming Integrated Circuitry

(71) Applicant: Micron Technology, Inc., Boise, ID (US)

(72) Inventors: Brenda Li, Boise, ID (US); David Daycock, Boise, ID (US)

(73) Assignee: Micron Technology, Inc., Boise, ID (US)

(21) Appl. No.: 18/778,329

(22) Filed: Jul. 19, 2024

Related U.S. Application Data
(60) Provisional application No. 63/606,678, filed on Dec. 6, 2023.

(51) Int. Cl. H10B 43/27; H10B 41/27

(52) U.S. Cl. CPC H10B 43/27; H10B 41/27

(57) ABSTRACT

Integrated circuitry comprises a three-dimensional (3D) array region comprising tiers of electronic components and a stair-step region. The 3D array region comprises vertically-alternating insulative tiers and conductive tiers that extend into the stair-step region. The stair-step region comprises at least one higher first tread that is immediately-laterally-adjacent a lower second tread along a direction in a vertical cross-section. A first flight of stairs extends vertically into the first tread along the direction and a second flight of stairs extends vertically into the second tread along the direction. One of the first flight of stairs and the second flight of stairs has positive slope and the other has negative slope. Methods are disclosed.

### TECHNICAL FIELD

Embodiments disclosed herein pertain to integrated circuitry, to memory circuitry, and to methods of forming integrated circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

The inventions herein were primarily motivated in challenges associated with the fabrication and final construction of memory circuitry. However, the invention has applicability to any fabrication and/or any structure having a 3D array region comprising tiers of electronic components and a stair-step region where the 3D array region comprises vertically-alternating insulative tiers and conductive tiers that extend into the stair-step region.

### BRIEF DESCRIPTION OF THE DRAWINGS

FIGS. 1-3 are diagrammatic cross-sectional views of portions of a construction that will comprise circuitry in accordance with an embodiment of the invention.

FIGS. 4-24 are diagrammatic sequential sectional and/or enlarged views of the construction of FIGS. 1-3, or portions thereof or alternate and/or additional embodiments, in process in accordance with some embodiments of the invention.

### DETAILED DESCRIPTION OF EXAMPLE EMBODIMENTS

Embodiments of the invention encompass methods used in forming integrated circuitry, for example a three-dimensional (3D) array comprising tiers of electronic components. Those electronic components may act as a single circuit component (e.g., a non-volatile and programmable charge-storage transistor of a vertical NAND string) or may combine with another electronic component or components to form a single circuit component (e.g., one capacitor and one transistor that in combination form a single circuit component in the form of one DRAM cell). Other memory as well as non-memory applications and electronic components are contemplated (e.g., diodes, resistors, inductors, fuses, amplifiers, etc.).

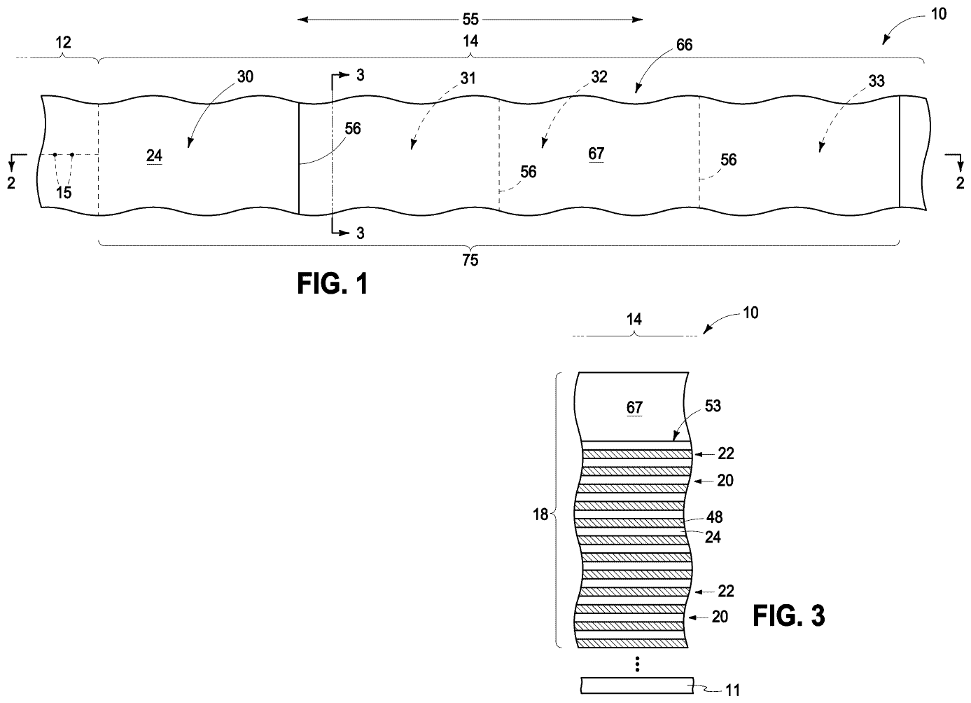

FIGS. 1-3 show an example construction 10 in a process of manufacture in accordance with method embodiments of the invention.

Construction 10 has a base substrate 11 that may have any combination of conductive/conductor/conducting, semiconductive/semiconductor/semiconducting, or insulative/insulator/insulating (i.e., electrically herein) materials. Various materials have been formed directly above base substrate 11. Materials may be aside, elevationally inward, or elevationally outward of the FIGS. 1-3-depicted materials. For example, other partially or wholly fabricated components of integrated circuitry may be provided somewhere above, about, or within base substrate 11.

A stack 18 has been formed above base substrate 11. Such comprises vertically-alternating first tiers 22 and second tiers 20 that extend from a three-dimensional (3D) array region 12 into to a stair-step region 14. First tiers 22 are conductive and second tiers 20 are insulative in a finished-circuitry construction, and such may or may not be so at this point of processing. In some embodiments, first tiers 22 are referred to as conductive tiers 22 and second tiers 20 are referred to as insulative tiers 20. Example thickness for each of tiers 20 and 22 is 20 to 60 nanometers, and such may be of different thicknesses relative one another including, for example, multiple different thickness insulative tiers and multiple different thickness conductive tiers. Example first tiers 22 are shown as comprising conductive material 48 (e.g., metal material and/or conductively-doped semiconductive material) and example second tiers 20 are shown as comprising insulative material 24 (e.g., silicon dioxide). Only a small number of tiers 20 and 22 is shown in FIGS. 1-3 and other figures, with more likely stack 18 comprising dozens, a hundred or more, etc. of tiers 20 and 22. 3D array region 12 comprises tiers of electronic components 15 in the finished-circuitry construction which may or may not exist at this point of processing. Example electronic components 15 are by way of example only shown schematically, in two columns, and which electrically couple (e.g., directly electrically couple) with conductive material 48 of individual conductive tiers 22. Likely many more electronic components 15 would be within 3D array region 12, with 3D array region likely being considerably larger than stair-step region 14.

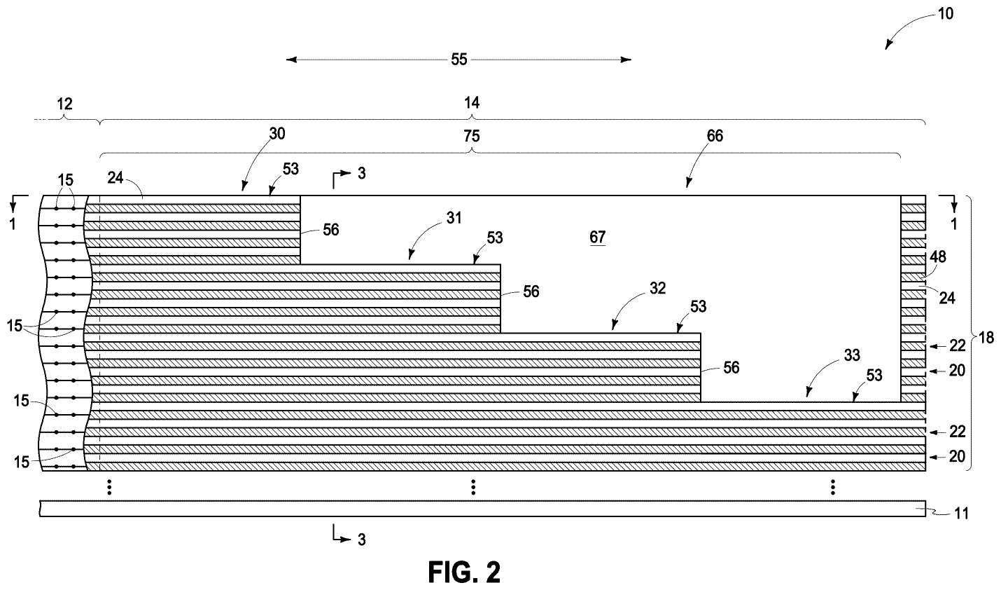

In some embodiments, stack 18 may be considered as comprising a cavity 66 comprising at least one higher first tread (e.g., tread 31) that is immediately-laterally-adjacent a lower second tread (e.g., tread 32) along a direction 55 in a vertical cross-section (e.g., that of FIG. 2). In this document, “immediately-laterally-adjacent” refers to two like features that do not have any other such like feature laterally there-between. First tread 31 and second tread 32 in one embodiment may be considered as collectively comprising a stair flight 75 that comprises an upper landing 30 that is higher than first tread 31 and a lower landing 33 that is lower than second tread 32. Alternately or additionally, upper landing 30 may be considered as comprising a second tread 30 or crest 30 and lower landing 33 may be considered as a first tread 33. Alternately or additionally, FIG. 2 may be considered as showing a plurality of first treads (e.g., 31, 33) and a plurality of second treads (e.g., 30, 32), with first treads 31, 33 individually alternating with immediately-laterally-adjacent second treads 30, 32 along direction 55. For ease of depiction, only four treads 30, 31, 32, and 33 are shown, with a construction 10 likely having many more tiers 20, 22 and, accordingly, many more first and second treads. Further, cavity 66 may include a mirror-image to the right in FIGS. 1 and 2 of analogous treads going from down to up (left-to-right and not shown).

Regardless, and by way of example only, multiple cavities 66 (not shown) might be formed in a stair-step region 14 to different depths for providing access to individual conductive tiers 22. Regardless, method embodiments encompass a cavity (e.g., 66) comprising at least one higher first tread (e.g., 31 or 32) that is immediately-laterally-adjacent a lower second tread (e.g., 32 or 33, respectively) along a direction 55 in a vertical cross-section. Insulative material 67 (e.g., silicon dioxide) has been formed in cavity 66 and by way of example has been planarized back to a top surface of insulative material 24 of top insulative tier 20. Treads 30, 31, 32, and 33 may be considered as having a riser 56 extending between immediately-laterally-adjacent such treads. Example risers 56 individually span eight alternating tiers 20, 22, although fewer or more such tiers may be spanned, and each riser need not span the same number of such tiers. In some embodiments, each of the first and second treads has a planar uppermost surface 53 and that is ideally horizontal.

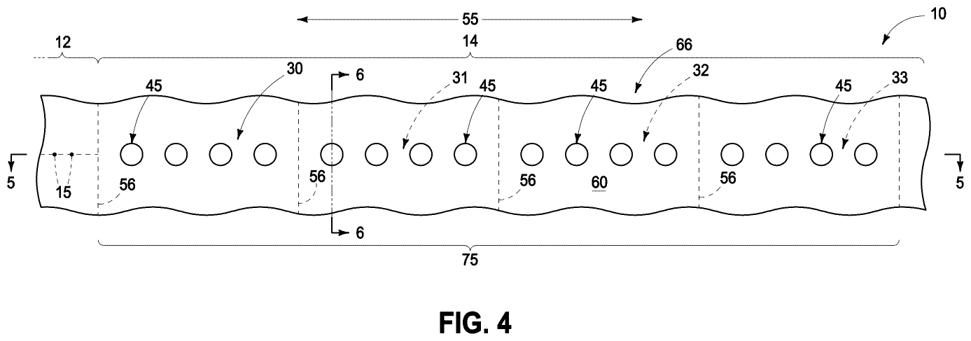

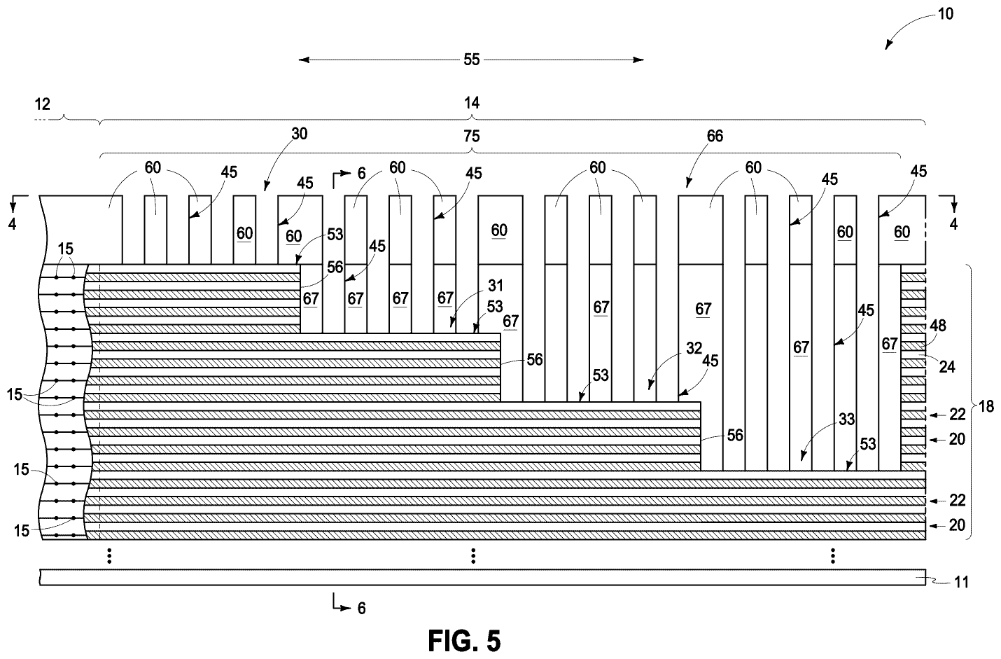

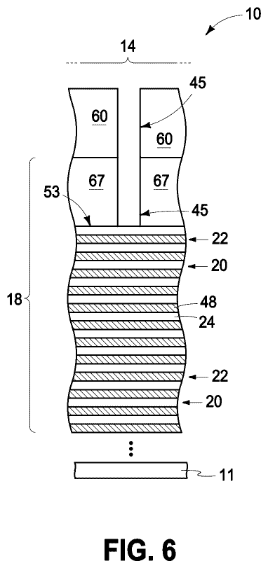

Referring to FIGS. 4-6, contact openings 45 have been formed to the first and second treads through insulative material 67, with multiple of contact openings 45 being laterally-spaced relative one another along direction 55 over each of the first and second treads. In one embodiment and as shown, hard-masking material 60 (e.g., an inorganic material such as silicon nitride or a silicon oxynitride), in some embodiments referred to as first hard-masking material 60, was previously formed directly above insulative material 67, with contact openings 45 being formed through hard-masking material 60 and then through insulative material 67. An example manner of forming contact openings 45 includes photolithography, for example forming and patterning corresponding openings through a photoresist layer (not shown) that is above hard-masking material 60 and using such as a mask while etching through materials 60 and 67.

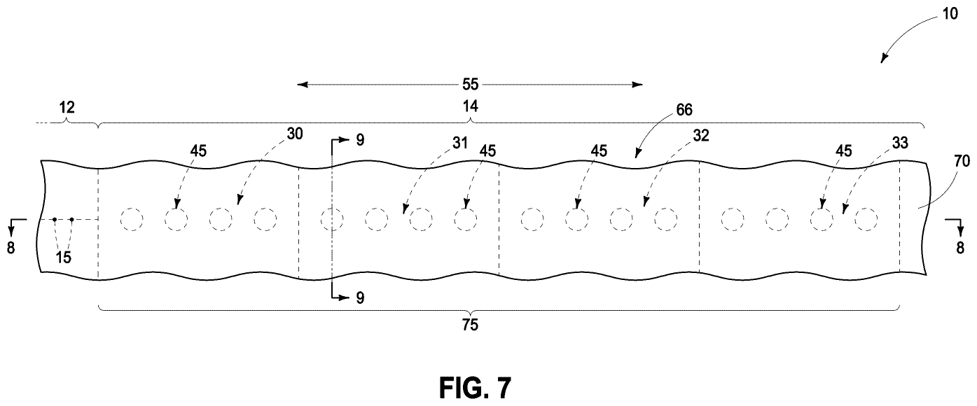

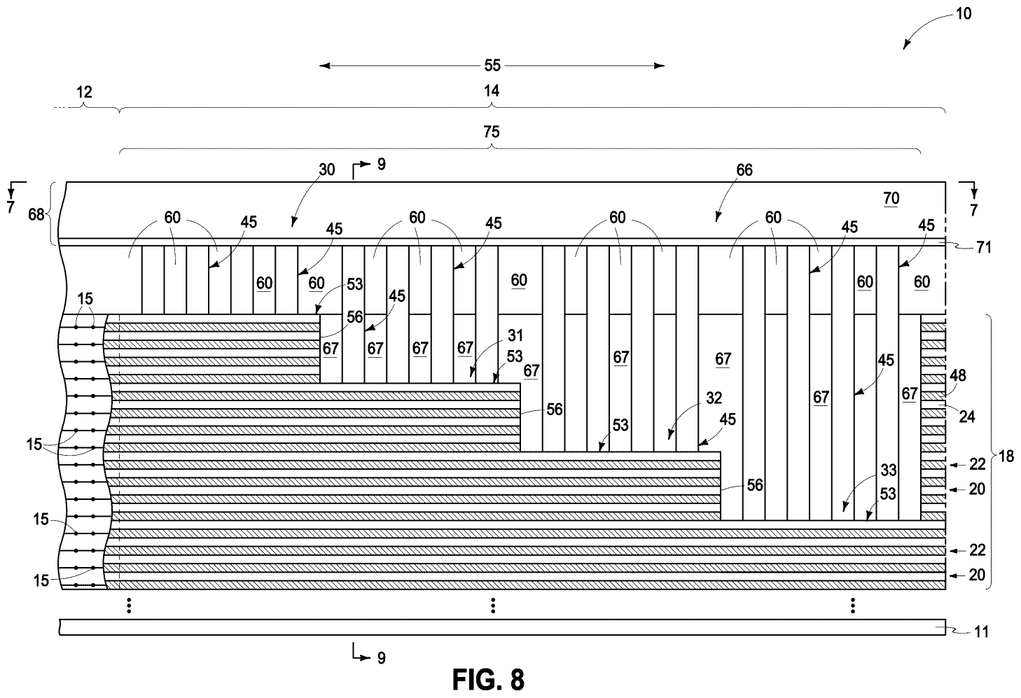

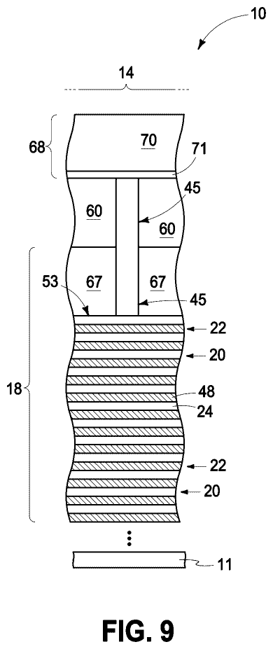

Referring to FIGS. 7-9, masking material 68 has been formed directly above insulative material 67 (and first hard-masking material 60 when present) and contact openings 45. In one embodiment and as shown, masking material 68 comprises photoresist 70 that has formed directly above hard-masking material 71 (e.g., carbon) and which in some embodiments is referred to as second hard-masking material 71, with second hard-masking material 71 being of different composition from that of first hard-masking material 60 (when present). Masking material 68 (e.g., material 71 thereof) is ideally formed in a highly non-conformal manner so little if any of it goes into contact openings 45.

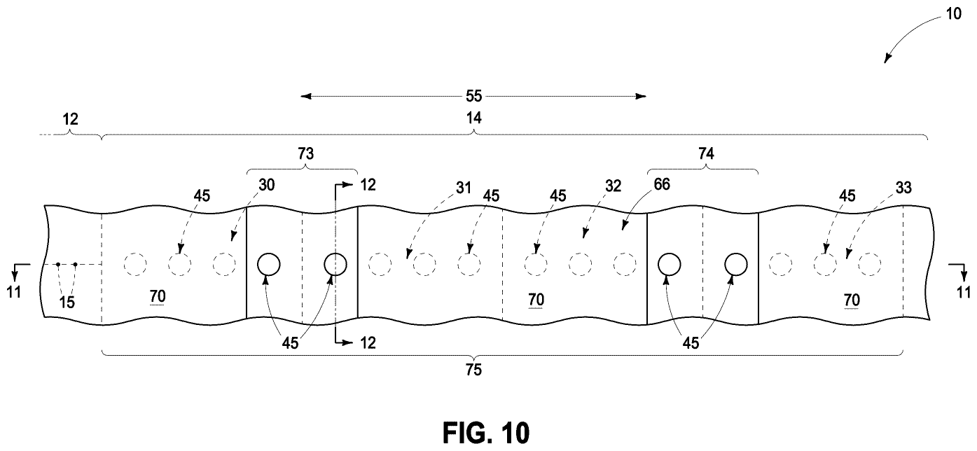

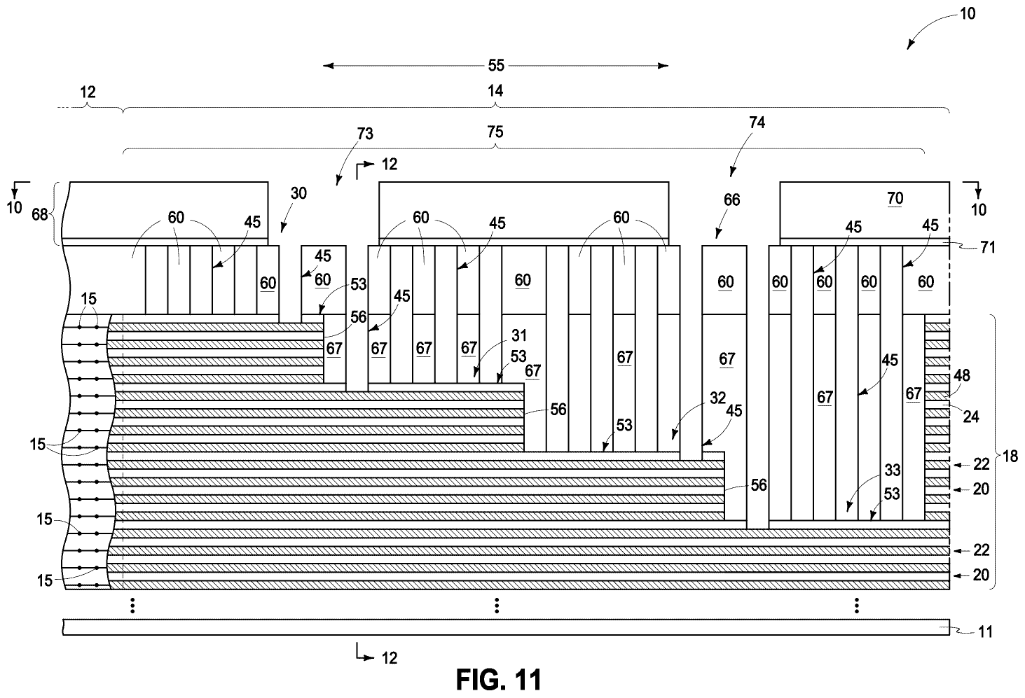

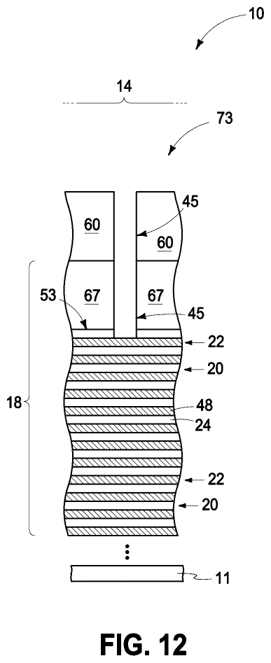

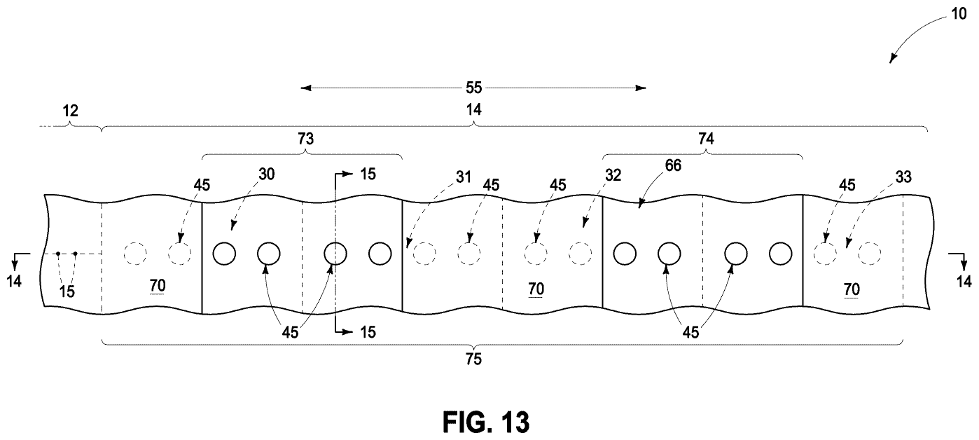

Referring to FIGS. 10-12, at least two openings (e.g., 73, 74) have been formed through masking material 68 and that are laterally-spaced relative one another along direction 55. At least two of such masking-material openings are immediately-laterally-adjacent one another (e.g., as are openings 73 and 74 in that there is no other masking-material opening there-between) and individually expose one of contact openings 45 on opposite ends (along direction 55) of first tread 32 and second tread 31. Example openings 73 and 74 in the depicted embodiment also expose one contact opening 45 in first tread 33/lower landing 33 and in second tread 30/upper landing 30. Additionally, in the depicted example, masking material 68 has been used as a mask while etching into top insulative tier 20 of each tread to extend contact openings 45 to the uppermost conductive material tread 22 of each tread. The top tier of each tread may alternately be a conductive tier 22 (not shown) and, if so, such initial etching into the individual treads need not occur.

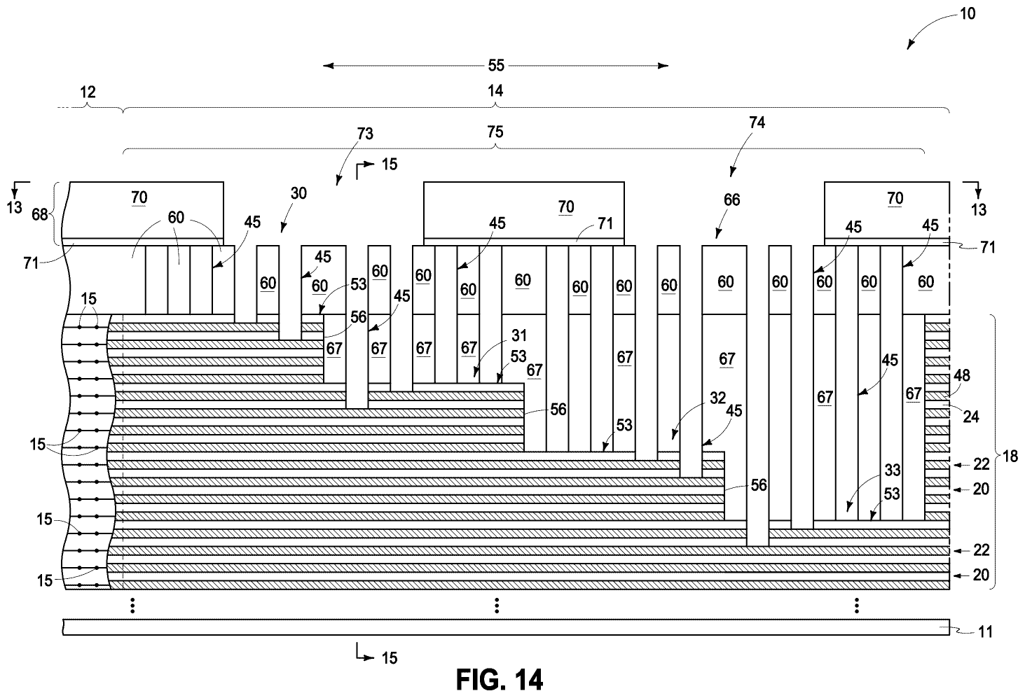

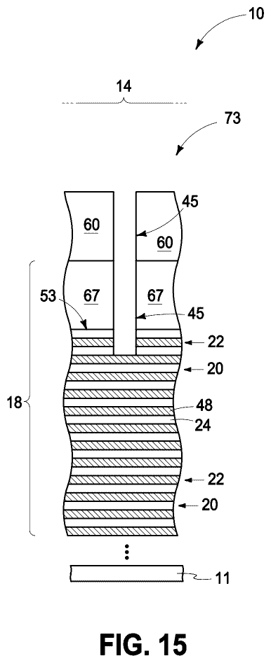

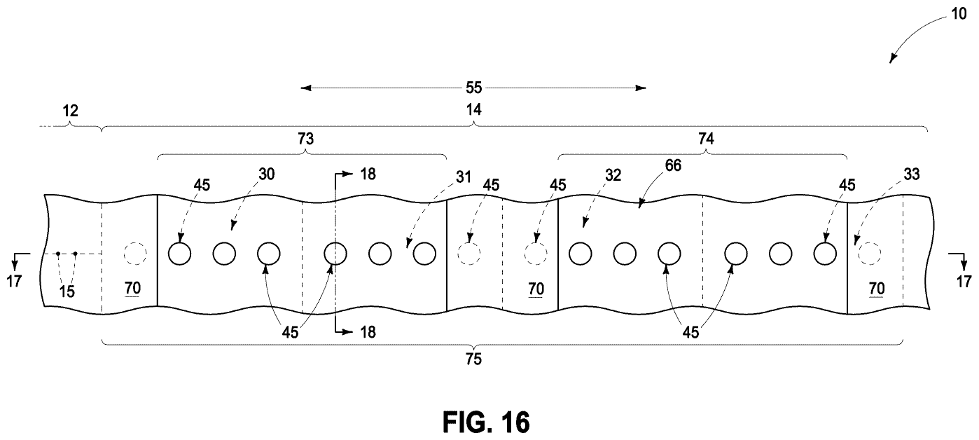

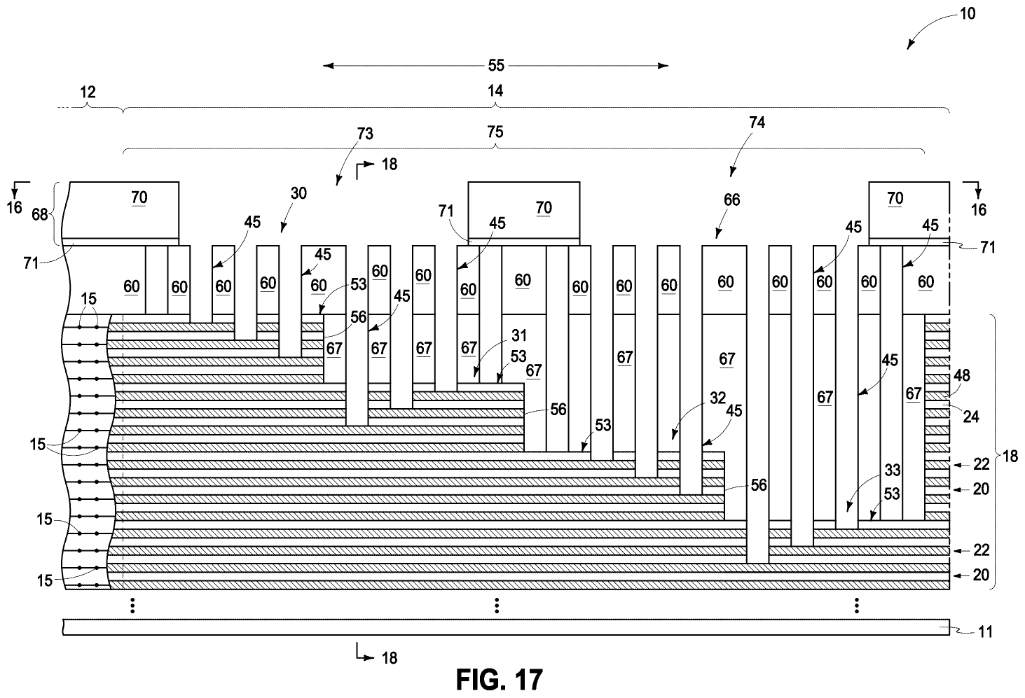

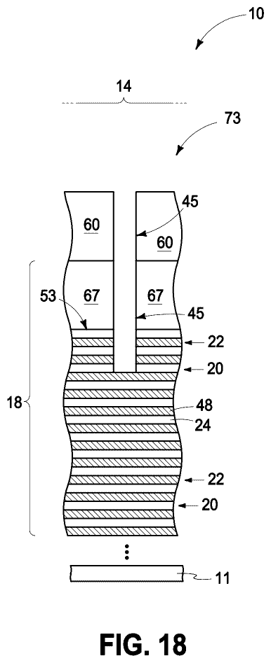

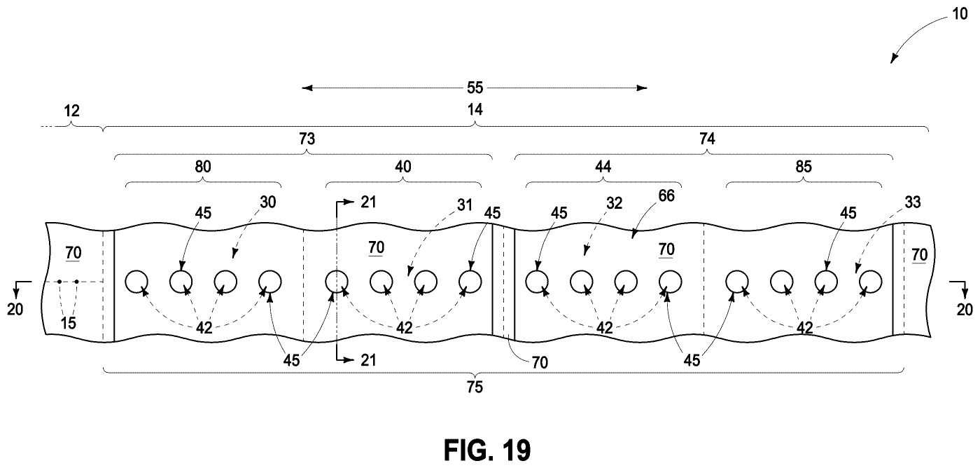

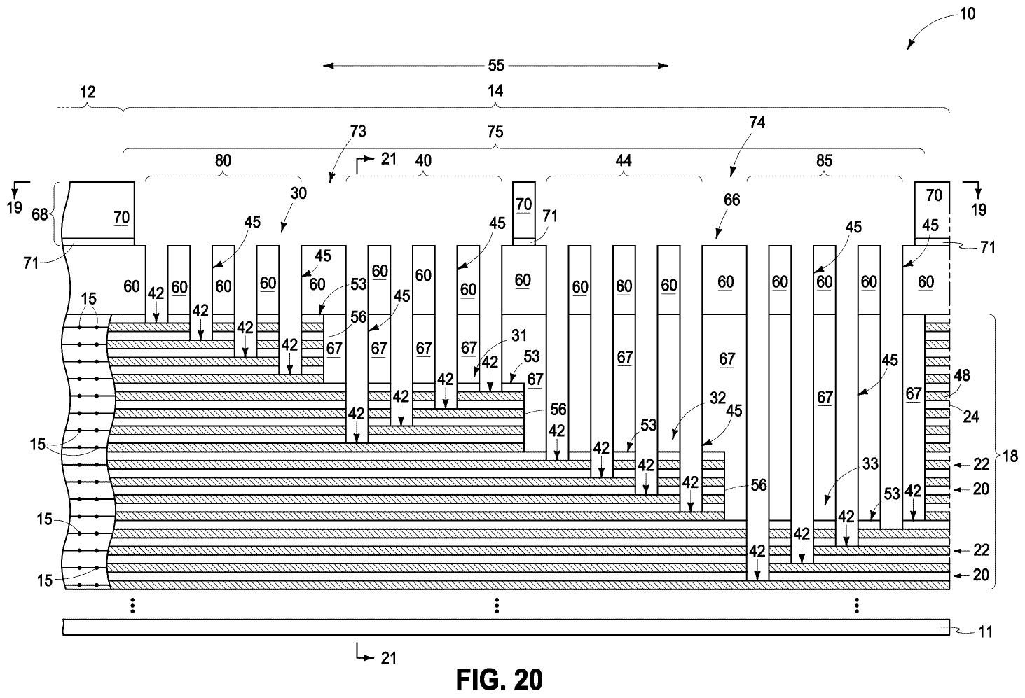

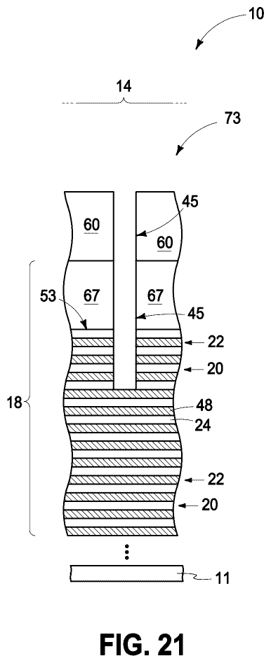

Referring to FIGS. 14-21, masking material 68 has been used in a plurality of alternating etching and lateral-trimming steps that etch into first tread 31 and second tread 32 (at least such treads) and widen masking-material openings 73 and 74 to form a first flight 40 of stairs 42 extending vertically into first tread 31 along direction 55 and a second flight 44 of stairs 42 extending vertically into second tread 32 along direction 55. By way of example, treads 31, 32, and 33 may be formed previously in an analogous manner. Regardless, one of first flight of stairs 42 and second flight of stairs 44 has positive slope (that may or may not be constant; e.g., first flight 40) and the other has negative slope (that may or may not be constant; e.g., second flight 44). In one embodiment and as shown, individual of the etching steps etches through only one of first tiers 22 and one of second tiers 20. Alternately, individual of the etching steps may etch through more first and second tiers (not shown), for example if forming secondary flights of stairs (not shown) with respect to each step in the direction orthogonal to direction 55. In one embodiment, the total number of stairs in the first flight and the total number of stairs in the second flight are the same. In one embodiment, the total number of stairs in the first flight and the total number of stairs in the second flight are each at least three and in one embodiment at least four. In one embodiment, immediately-laterally-adjacent of stairs 42 in the first and second flights of stairs comprise a plurality of the insulative and conductive tiers. In one embodiment where photoresist 70, second hard-masking material 71, and first hard-masking material are present, the lateral trimming steps laterally trim photoresist 70 and second hard-masking material 71 selectively relative to first hard-masking material 60. Stairs 42 are shown by way of example only as being circular in horizontal cross-section, and other cross-sectional shapes are of course contemplated.

In one embodiment and as shown, the plurality of alternating etching and lateral-trimming steps form an upper flight 80 of stairs 42 extending vertically into upper landing 30/second tread 30 along direction 55. Further, the plurality of alternating etching and lateral-trimming steps forms a lower flight 85 of stairs 42 extending vertically into lower landing 33/first tread 33 along direction 55. One of upper flight 80 and lower flight 85 has positive slope (that may or may not be constant; e.g., lower flight 85) and the other has negative slope (that may or may not constant; e.g., upper flight 80). In one embodiment, the plurality of alternating etching and lateral-trimming steps forms individual of the first treads where there are a plurality of such first treads (e.g., first treads 31 and 33) to comprise such first flight (e.g., 40, 85. respectively) and individual of the second treads (e.g., 30 and 32) to comprise such second flight (e.g., 80, 44, respectively).

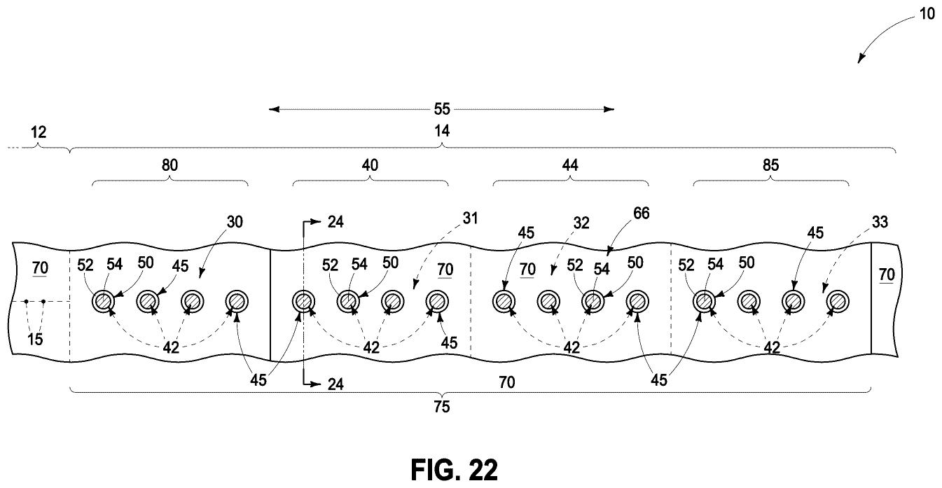

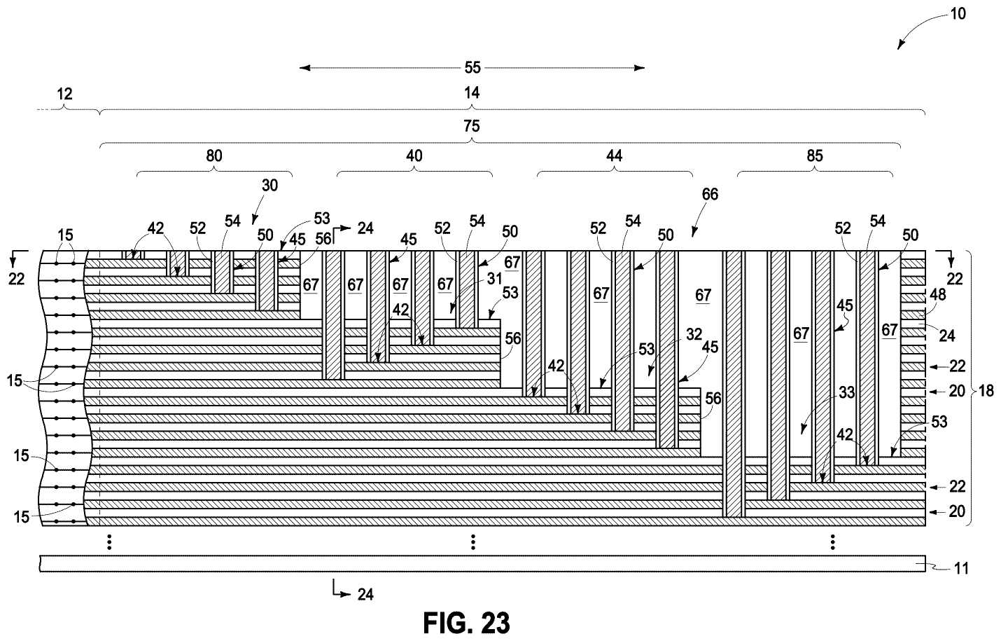

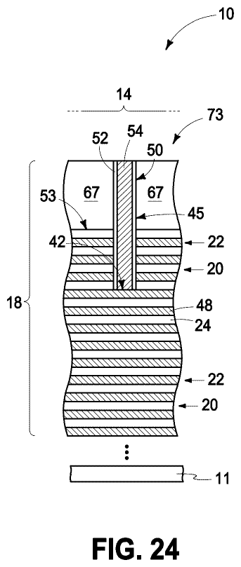

Referring to FIGS. 22-24, a conductive via construction 50 (e.g., comprising a conductive core 54 having an insulative lining 52 there-about) has been formed in individual contact openings 45 and that is directly electrically coupled with conductive material 48 of individual stairs 42. Remaining masking material 68 (not shown) has ideally been removed prior thereto.

Any other attribute(s) or aspect(s) as shown and/or described herein with respect to other embodiments may be used in the embodiments shown and described with reference to the above embodiments.

Alternate embodiment constructions may result from method embodiments described above, or otherwise. Regardless, embodiments of the invention encompass circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

In some embodiments, integrated circuitry (e.g., 10) comprises a three-dimensional (3D) array region (e.g., 12) comprising tiers of electronic components (e.g., 15) and a stair-step region (e.g., 14). The 3D array region comprises vertically-alternating insulative tiers (e.g., 20) and conductive tiers (e.g., 22) that extend into the stair-step region. The stair-step region comprises at least one higher first tread (e.g., 31 or 32) that is immediately-laterally-adjacent a lower second tread (e.g., 32 or 33, respectively) along a direction (e.g., 55) in a vertical cross-section (e.g., FIG. 2). A first flight (e.g., 40) of stairs (e.g., 42) extends vertically into the first tread along the direction and a second flight (e.g., 44) of stairs extends vertically into the second tread along the direction. One of the first flight of stairs and the second flight of stairs has positive slope (e.g., flight 40) and the other has negative slope (e.g., flight 44). Any other attribute(s) or aspect(s) as shown and/or described herein with respect to other embodiments may be used.

In some embodiments, memory circuitry (e.g., 10) comprises a three-dimensional (3D) memory array region (e.g., 12) comprising tiers of memory cells (e.g., 15) and a stair-step region (e.g., 14). The 3D memory array region comprises vertically-alternating insulative tiers (e.g., 20) and conductive tiers (e.g., 22) that extend into the stair-step region. The stair-step region comprises at least one higher first tread (e.g., 31) that is immediately-laterally-adjacent a lower second tread (e.g., 32) along a direction (e.g., 55) in a vertical cross-section (e.g., FIG. 2). A first flight (e.g., 40) of stairs (e.g., 42) extends vertically into the first tread along the direction and a second flight (e.g., 44) of stairs extends vertically into the second tread along the direction. One of the first flight of stairs and the second flight of stairs has positive slope (e.g., flight 40) and the other has negative slope (e.g., flight 44). Any other attribute(s) or aspect(s) as shown and/or described herein with respect to other embodiments may be used.

In method embodiments, forming first and second treads as described herein first may reduce the number of more difficult contact-opening etches that have higher aspect ratios.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method of forming integrated circuitry comprises forming a stack comprising vertically-alternating first tiers and second tiers that extend from a three-dimensional (3D) array region into a stair-step region. The first tiers are conductive and the second tiers are insulative in a finished-circuitry construction and the 3D array region comprises tiers of electronic components in the finished circuitry construction. The stack in the stair-step region comprises a cavity comprising at least one higher first tread that is immediately-laterally-adjacent a lower second tread along a direction in a vertical cross-section. Contact openings to the first and second treads are formed through insulative material that is in the cavity directly above the first and second treads. Multiple of the contact openings are laterally-spaced relative one another along the direction over each of the first and second treads. Masking material is formed directly above the insulative material and the contact openings. At least two openings are formed through the masking material that are laterally-spaced relative one another along the direction. At least two of the masking-material openings are immediately-laterally-adjacent one another and individually expose one of the contact openings on opposite ends of the first and second treads. The masking material is used in a plurality of alternating etching and lateral-trimming steps that etch into the first and second treads and widen the masking-material openings to form a first flight of stairs extending vertically into the first tread along the direction and a second flight of stairs extending vertically into the second tread along the direction. One of the first flight of stairs and the second flight of stairs has positive slope and the other has negative slope.

In some embodiments, integrated circuitry comprises a three-dimensional (3D) array region comprising tiers of electronic components and a stair-step region. The 3D array region comprises vertically-alternating insulative tiers and conductive tiers that extend into the stair-step region. The stair-step region comprises at least one higher first tread that is immediately-laterally-adjacent a lower second tread along a direction in a vertical cross-section. A first flight of stairs extends vertically into the first tread along the direction and a second flight of stairs extends vertically into the second tread along the direction. One of the first flight of stairs and the second flight of stairs has positive slope and the other has negative slope.

In some embodiments, memory circuitry comprises a three-dimensional (3D) memory array region comprising tiers of memory cells and a stair-step region. The 3D memory array region comprises vertically-alternating insulative tiers and conductive tiers that extend into the stair-step region. The stair-step region comprises at least one higher first tread that is immediately-laterally-adjacent a lower second tread along a direction in a vertical cross-section. A first flight of stairs extends vertically into the first tread along the direction and a second flight of stairs extends vertically into the second tread along the direction. One of the first flight of stairs and the second flight of stairs has positive slope and the other has negative slope.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method of forming integrated circuitry comprising:
forming a stack comprising vertically-alternating first tiers and second tiers that extend from a three-dimensional (3D) array region into a stair-step region, the first tiers being conductive and the second tiers being insulative in a finished-circuitry construction and the 3D array region comprising tiers of electronic components in the finished circuitry construction, the stack in the stair-step region comprising a cavity comprising at least one higher first tread that is immediately-laterally-adjacent a lower second tread along a direction in a vertical cross-section;
forming contact openings to the first and second treads through insulative material that is in the cavity directly above the first and second treads, multiple of the contact openings being laterally-spaced relative one another along the direction over each of the first and second treads;
forming masking material directly above the insulative material and the contact openings;
forming at least two openings through the masking material that are laterally-spaced relative one another along the direction, at least two of the masking-material openings being immediately-laterally-adjacent one another and individually exposing one of the contact openings on opposite ends of the first and second treads; and
using the masking material in a plurality of alternating etching and lateral-trimming steps that etch into the first and second treads and widen the masking-material openings to form a first flight of stairs extending vertically into the first tread along the direction and a second flight of stairs extending vertically into the second tread along the direction, one of the first flight of stairs and the second flight of stairs having positive slope and the other having negative slope.

2. The method of claim 1 wherein individual of the etching steps etch through only one of the first tiers and one of the second tiers.

3. The method of claim 1 wherein the masking material comprises photoresist directly above hard-masking material.

4. The method of claim 1 comprising hard-masking material directly above the insulative material, the contact openings being formed through the hard-masking material and then through the insulative material, the masking material being formed directly above the hard-masking material.

5. The method of claim 1 comprising:
first hard-masking material directly above the insulative material, the contact openings being formed through the first hard-masking material and then through the insulative material, the masking material being formed directly above the first hard-masking material; and
the masking material comprising photoresist directly above second hard-masking material that is of different composition from that of the first hard-masking material, the lateral trimming steps laterally trimming the photoresist and second hard-masking material selectively relative to the first hard-masking material.

6. The method of claim 1 comprising forming a conductive-via construction that is directly electrically coupled with conductive material of individual of the stairs.

7. The method of claim 1 wherein,
the first tread and the second tread collectively comprise a stair flight, and further comprising:
the stair flight comprising an upper landing that is higher than the first tread and a lower landing that is lower than the second tread;
the plurality of alternating etching and lateral-trimming steps forming an upper flight of stairs extending vertically into the upper landing along the direction;
the plurality of alternating etching and lateral-trimming steps forming a lower flight of stairs extending vertically into the lower landing along the direction; and
one of the upper flight of stairs and the lower flight of stairs having positive slope and the other having negative slope.

8. The method of claim 1 comprising a plurality of the first treads and a plurality of the second treads, the first treads individually alternating with immediately-laterally-adjacent of the second treads along the direction, the plurality of alternating etching and lateral-trimming steps forming individual of the first treads to comprise said first flight and individual of the second treads to comprise said second flight.

9. Integrated circuitry comprising:
a three-dimensional (3D) array region comprising tiers of electronic components and a stair-step region, the 3D array region comprising vertically-alternating insulative tiers and conductive tiers that extend into the stair-step region;
the stair-step region comprising at least one higher first tread that is immediately-laterally-adjacent a lower second tread along a direction in a vertical cross-section, and
a first flight of stairs extending vertically into the first tread along the direction and a second flight of stairs extending vertically into the second tread along the direction, one of the first flight of stairs and the second flight of stairs having positive slope and the other having negative slope.

10. The integrated circuitry of claim 9 wherein each of the first and second treads has a planar uppermost surface.

11. The integrated circuitry of claim 10 wherein the surface is horizontal.

12. The integrated circuitry of claim 9 wherein the first tread and the second tread are within a cavity in the vertically-alternating insulative tiers and conductive tiers in the stair-step region, immediately-laterally-adjacent of the stairs in the first and second flights of stairs comprising a plurality of the insulative and conductive tiers.

13. The integrated circuitry of claim 12 comprising a conductive-via construction that is directly electrically coupled with conductive material of individual of the stairs.

14. The integrated circuitry of claim 13 wherein the conductive-via construction is in the cavity.

15. The integrated circuitry of claim 9 wherein the total number of the stairs in the first flight and the total number of the stairs in the second flight are the same.

16. The integrated circuitry of claim 9 wherein the total number of the stairs in the first flight and the total number of the stairs in the second flight are each at least three.

17. The integrated circuitry of claim 16 wherein the total number of the stairs in the first flight and the total number of the stairs in the second flight are each at least four.

18. The integrated circuitry of claim 9 wherein,
the first tread and the second tread collectively comprise a stair flight, and further comprising:
the stair flight comprising an upper landing that is higher than the first tread and a lower landing that is lower than the second tread;
an upper flight of stairs extending vertically into the upper landing along the direction;
a lower flight of stairs extending vertically into the lower landing along the direction; and
one of the upper flight of stairs and the lower flight of stairs having positive slope and the other having negative slope.

19. The integrated circuitry of claim 9 comprising a plurality of the first treads and a plurality of the second treads, the first treads individually alternating with immediately-laterally-adjacent of the second treads along the direction, individual of the first treads comprising said first flight, individual of the second treads comprising said second flight.

20. Memory circuitry comprising:
a three-dimensional (3D) memory array region comprising tiers of memory cells and a stair-step region, the 3D memory array region comprising vertically-alternating insulative tiers and conductive tiers that extend into the stair-step region;
the stair-step region comprising at least one higher first tread that is immediately-laterally-adjacent a lower second tread along a direction in a vertical cross-section; and
a first flight of stairs extending vertically into the first tread along the direction and a second flight of stairs extending vertically into the second tread along the direction, one of the first flight of stairs and the second flight of stairs having positive slope and the other having negative slope.
